(19) United States
(12) Patent Application Publication
(10) Pub. No.: US 2024/0395950 A1
(43) Pub. Date: Nov. 28, 2024

(54) SENSOR PACKAGE STRUCTURE AND MANUFACTURING METHOD THEREOF

(71) Applicant: TONG HSING ELECTRONIC INDUSTRIES, LTD., Taipei City (TW)

(72) Inventors: JUI-HUNG HSU, Hsin-Chu County (TW); LI-CHUN HUNG, Hsin-Chu County (TW)

(21) Appl. No.: 18/472,256

(22) Filed: Sep. 22, 2023

(30) Foreign Application Priority Data
May 26, 2023 (TW) 112119596

(51) Int. Cl. H01L 31/0203; H01L 23/00; H01L 23/31; H01L 23/498; H01L 27/146

(52) U.S. Cl. CPC H01L 31/0203; H01L 23/3128; H01L 23/49816; H01L 24/48; H01L 27/14618; H01L 27/14632; H01L 2224/48091; H01L 2224/48227; H01L 2924/181

(57) ABSTRACT

A sensor package structure and a manufacturing method thereof are provided. The sensor package structure includes a substrate, a sensing chip, a light-permeable element, a photoresist layer, and a die-bonding film layer. The sensing chip is disposed on the substrate, and an upper surface of the sensing chip has a sensing region. The light-permeable element is disposed above the sensing chip. The photoresist layer is disposed on a first surface of the light-permeable element. The die-bonding film layer is adhered between the sensing chip and the light-permeable element and surrounds the sensing region.

### CROSS-REFERENCE TO RELATED PATENT APPLICATION

This application claims the benefit of priority to Taiwan Patent Application No. 112119596, filed on May 26, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure and a manufacturing method thereof, and more particularly to a sensor package structure and a manufacturing method thereof.

### BACKGROUND OF THE DISCLOSURE

Existing image sensors, such as CMOS image sensors, increase a sensing area of a sensor chip in pursuit of higher resolution. However, enlarging the area of the sensing region will reduce a distance between an edge of the sensing chip and an edge of the sensing region (i.e., a space available for dispensing glues on the sensing chip will be reduced), which can result in difficulties in dispensing glue and form an unstable colloidal structure. Therefore, the light-permeable glass sheet easily tilts when glued on the colloidal structure, thereby reducing the reliability of the sensor package structure.

Therefore, how to improve structural design of the sensor package structure and overcome the above-mentioned inadequacies has become an important issue to be addressed in the relevant art.

### SUMMARY OF THE DISCLOSURE

In response to the above-referenced technical inadequacy, the present disclosure provides a sensor package structure and a manufacturing method thereof for improving the stability and reliability of the sensor package structure.

In one aspect, the present disclosure is to provide a sensor package structure, which includes a substrate, a sensing chip, a light-permeable element, a photoresist layer, and a die-bonding film layer. The sensing chip is disposed on the substrate, and an upper surface of the sensing chip has a sensing region. The light-permeable element is disposed above the sensing chip. The photoresist layer is disposed on a first surface of the light-permeable element. The die-bonding film layer is adhered between the sensing chip and the photoresist layer and surrounds the sensing region.

In another aspect, the present disclosure is to provide a method of manufacturing a sensor package structure, which includes: providing a light-permeable element and forming a photoresist layer on a first surface of the light-permeable element, wherein a plurality of first windows are formed in the photoresist layer; forming a die-bonding film layer on a base layer, wherein the die-bonding film layer has a plurality of second windows; inverting the light-permeable element onto the die-bonding film layer, such that the photoresist layer is adhered to the die-bonding film layer, and the plurality of the first windows respectively correspond to the plurality of the second windows; performing a slicing process to slice the light-permeable element, the photoresist layer, and the die-bonding film layer through a slicing process to form at least one package cover; providing a substrate and placing a sensing chip onto the substrate to be electrically connected to the substrate, wherein an upper surface of the sensing chip has a sensing region; and placing the at least one package cover onto the sensing chip, wherein the at least one package cover and the sensing chip jointly form an enclosed space, and the sensing region is located in the enclosed space.

Therefore, in the sensor package structure and the manufacturing method thereof provided by the present disclosure, by using the die-bonding film layer (i.e., Die Attach Film) instead of the existing adhesive glue as an adhesive material between the light-permeable element and the sensing chip, a width of the adhesive material can be precisely controlled to form a stable colloidal structure on a limited carrying area of the sensing chip and address an issue of poor reliability of the existing colloidal structure due to insufficient carrying area of the existing sensing chip.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a sensor package structure according to a first embodiment of the present disclosure;

FIG. 2 is a schematic enlarged view of part II of FIG. 1;

FIG. 3 is a flowchart of a method of manufacturing a sensor package structure according to a second embodiment of the present disclosure; and

FIGS. 4 to 10 are schematic views of the steps of the method of manufacturing the sensor package structure according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

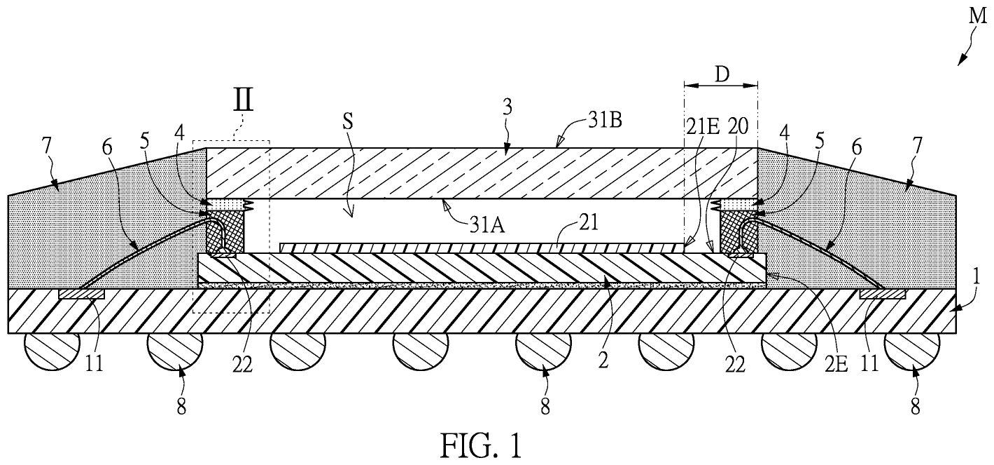

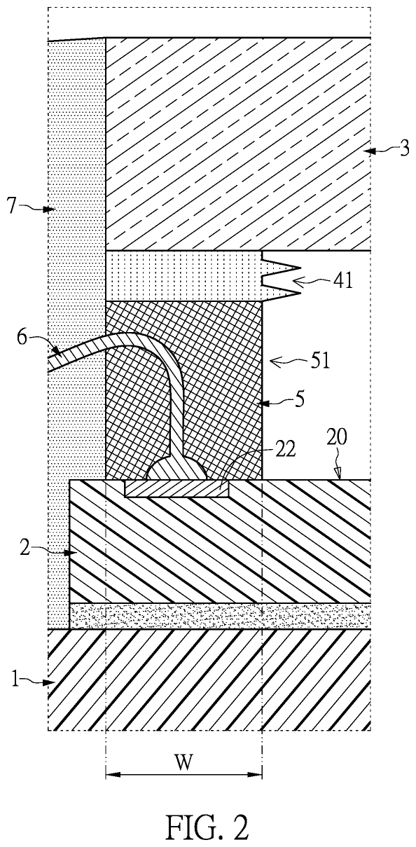

Referring to FIG. 1 and FIG. 2, a first embodiment of the present disclosure provides a sensor package structure M, which includes a substrate 1, a sensing chip 2, a light-permeable element 3, a photoresist layer 4, and a die-bonding film layer 5. The sensing chip 2 is disposed on the substrate 1, and an upper surface 20 of the sensing chip 2 has a sensing region 21 and a carrying region outside the sensing region 21. Specifically, the carrying region is the region of the upper surface 20 excluding the sensing region 21. The light-permeable element 3 is disposed above the sensing chip 2. The light-permeable element 3 has a first surface 31A and a second surface 31B opposite to each other. The first surface 31A faces the sensing region 21, and the second surface 31B faces towards outside the sensor package structure M. The photoresist layer 4 is disposed on the first surface 31A of the light-permeable element 3. The die-bonding film layer 5 is adhered between the sensing chip 2 and the photoresist layer 4. The die-bonding film layer 5 and the photoresist layer 4 jointly surround the sensing region 21. The die-bonding film layer 5 and the photoresist layer 4 separate the sensing chip 2 from the light-permeable element 3. Moreover, the light-permeable element 3, the photoresist layer 4, and the die-bonding film layer 5 jointly form an encapsulation cover C. The encapsulation cover C covers the sensing chip 2 and forms an enclosed space S, and the sensing region 21 is located in the enclosed space S.

For example, the sensing chip 2 can be a complementary metal oxide semiconductor (CMOS) sensing die, but the present disclosure is not limited thereto. Light from the external environment, such as visible light, can pass through the light-permeable element 3 and be received by the sensing region 21 to form an image. In the first embodiment, the light-permeable element 3 is illustrated as a plate-shaped transparent glass, but the present disclosure is not limited thereto. In addition, the photoresist layer 4 can be made of a light-absorbing material, such as black photoresist or black ink, to prevent flare in the sensor package structure M. Furthermore, a rough surface 41 can be formed on a side of the photoresist layer 4 facing the sensing region 21. As shown in FIG. 2, a contour of the rough surface 41 is a zigzag structure, which can achieve the effect of blocking stray light and reduce the probability of stray light incident on the packaging structure entering the sensing region 21, thereby effectively reducing flare generated in the sensor package structure M.

In the first embodiment, the die-bonding film layer 5 is a die attach film (DAF), which has good stability, adhesion and cuttability, and can be separated from a carrier (e.g., the light-permeable element 3 and the photoresist layer 4) during cutting without excessive deformation.

In the existing sensor package structure, the light-permeable element and the sensing chip adhere to each other through liquid or pasty glue. However, it is difficult to control the amount of such liquid or pasty glues on the surface of the sensing chip because of an insufficient area of the sensing chip. Excessive glue on the surface of the sensing chip can result in overflow, but inadequate glue can also result in insufficiency of the adhesion strength between the light-permeable element and the sensing chip and impact the overall stability of the packaging structure. In addition, since the amount of glue is difficult to control, a thickness of the cured colloidal structure formed by the glue may be uneven, which causes the light-permeable element to tilt or crack, and results in a decrease in the yield and reliability of the product.

In contrast, the sensor packaging structure M provided by the present disclosure uses the die-bonding film layer 5 as an adhesive material, which can provide good support and is not limited by the carrying area on the surface of the sensing chip. In other words, the die-bonding film layer 5 will not occupy too much of the carrying area on the surface of the sensing chip 2, and the area of the sensing region 21 can be increased as much as possible. An outer edge 21E of the sensing region 21 can extend toward an outer edge 2E of the sensing chip 2 as much as possible. Preferably, a distance D between the outer edge 21E of the sensing region 21 and the outer edge 2E of the sensing chip 2 is less than 400 μm.

Furthermore, in the related art, the cured colloidal structure is prone to deformation. For example, the middle part of the cured colloidal structure is narrow and the upper and lower parts of the cured colloidal structure are wider, such that a side contour of the cured colloidal structure is arc-shaped. In other words, the structural size of the cured colloidal structure cannot be precisely controlled.

In contrast, a height and a width of the die-bonding film layer 5 in the present disclosure can be precisely controlled. Preferably, the width W of the die-bonding film layer 5 is less than 100 μm. The die-bonding film layer 5 can further prevent the light-permeable element 3 from excessively tilting or being broken. Preferably, an inclination of the first surface 31A of the light-permeable element 3 relative to a horizontal plane is less than 10 μm. A method of measuring the inclination is to measure a height difference between the highest point and the lowest point of four corners of the light-permeable element 3 (e.g., taking the light-permeable element 3 as a quadrangle). Thus, if the lowest point is on the horizontal plane, the inclination is the distance between the highest point and the horizontal plane.

As shown in FIG. 2, through the excellent characteristics of the die-bonding film layer 5 of the sensor package structure M provided by the present disclosure, a side of the die-bonding film layer 5 facing the sensing region 21 can has a flat surface 51 to prevent the die-bonding film layer 5 from touching or covering the sensing region 21. It should be noted that, a material of the die-bonding film layer 5 can include a non-transparent material, which can also be used to prevent glare.

The sensor packaging structure M may further include a plurality of metal wires 6 that are electrically connected between the sensing chip 2 and the substrate 1. Specifically, the substrate 1 includes a plurality of first pads 11, the sensing chip 2 further includes a plurality of second pads 22, and the plurality of second pads 22 are disposed on the upper surface 20 and embedded under the die-bonding film layer 5. One end of each of the plurality of metal wires 6 is connected to the plurality of first pads 11, and another end of each of the plurality of metal wires 6 is connected to the plurality of second pads 22 and embedded into the die-bonding film layer 5. Therefore, the die-bonding film layer 5 can be a film-over-wire (FOW) structure. In addition, any of the metal wires 6 can be formed by normal bonding or reverse bonding, but the present disclosure is not limited thereto.

The sensor package structure M further includes an encapsulation compound 7 that is disposed on the substrate 1. The sensing chip 2, a part of the light-permeable element 3, the photoresist layer 4, the die-bonding film layer 5, and the plurality of metal wires 6 are embedded into the encapsulation compound 7, and the second surface 31B of the light-permeable element 3 is exposed from the encapsulation compound 7. For example, the encapsulation compound 7 can be a liquid compound or a molding compound, but the present disclosure is not limited thereto. Moreover, the sensor package structure M can be soldered and fixed onto an electronic component (not shown in the figures) through a plurality of solder balls 8, such that the chip package structure M is electrically coupled to the electronic component.

### Second Embodiment

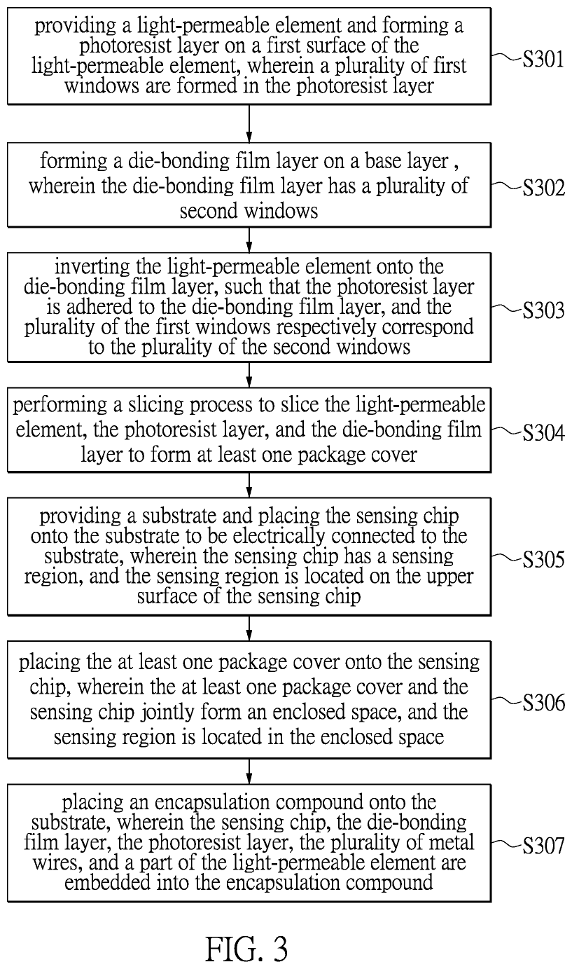

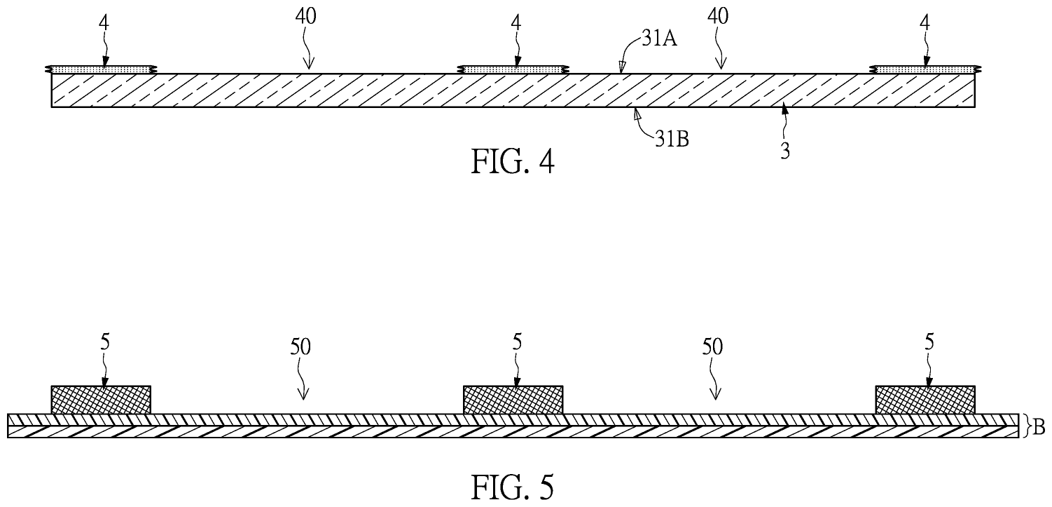

Referring to FIG. 3 to FIG. 10, FIG. 3 is a flowchart of a method of manufacturing a sensor package structure according to a second embodiment of the present disclosure, and FIGS. 4 to 10 are schematic views of the steps of the method of manufacturing the sensor package structure according to the second embodiment of the present disclosure. It should be noted that the characteristics of all of the elements in the method of manufacturing the sensor package structure provided by the second embodiment are similar to those of the first embodiment, and will not be reiterated herein. In addition, the second embodiment is illustrated by the sensor package structure M shown in FIG. 1 and FIG. 2. That is to say, the sensor packaging structure shown in FIG. 1 and FIG. 2 can be manufactured by the manufacturing method of the sensor packaging structure in the second embodiment.

A second embodiment of the present disclosure provides a method of manufacturing a sensor package structure, which includes:

Step S301: providing a light-permeable element 3 and forming a photoresist layer 4 on a first surface 31A of the light-permeable element 3, wherein a plurality of first windows 40 are formed in the photoresist layer 4.

Regarding step S301, as shown in FIG. 4, the light-permeable element 3 includes the first surface 31A and a second surface 31B, and a photoresist layer 4 having a plurality of first windows 40 is formed on the first surface 31A. For example, the step of forming the photoresist layer 4 on the first surface 31A of the light-permeable element 3 further includes: performing a coating process to form a preformed photoresist layer (i.e., where the first window 40 has yet to be formed) on the first surface 31A of the light-permeable element 3, and performing an etching process (e.g., a lithography process or a laser etching process) to form the plurality of first windows 40 on the preformed photoresist layer (i.e., the photoresist layer 4 with the plurality of first windows 40 in FIG. 3). Alternatively, for example, the step of forming the photoresist layer 4 on the first surface 31A of the light-permeable element 3 further includes: performing a screen printing process to directly form the photoresist layer 4 that has the plurality of first windows 40 on the first surface 31A of the light-permeable element 3. Therefore, the method of forming the photoresist layer 4 is not limited by the present disclosure.

Step S302: forming a die-bonding film layer 5 on a base layer B, wherein the die-bonding film layer 5 has a plurality of second windows 50.

Step S303: inverting the light-permeable element 3 onto the die-bonding film layer 5, such that the photoresist layer 4 is adhered to the die-bonding film layer 5, and the plurality of the first windows 40 respectively correspond to the plurality of the second windows 50.

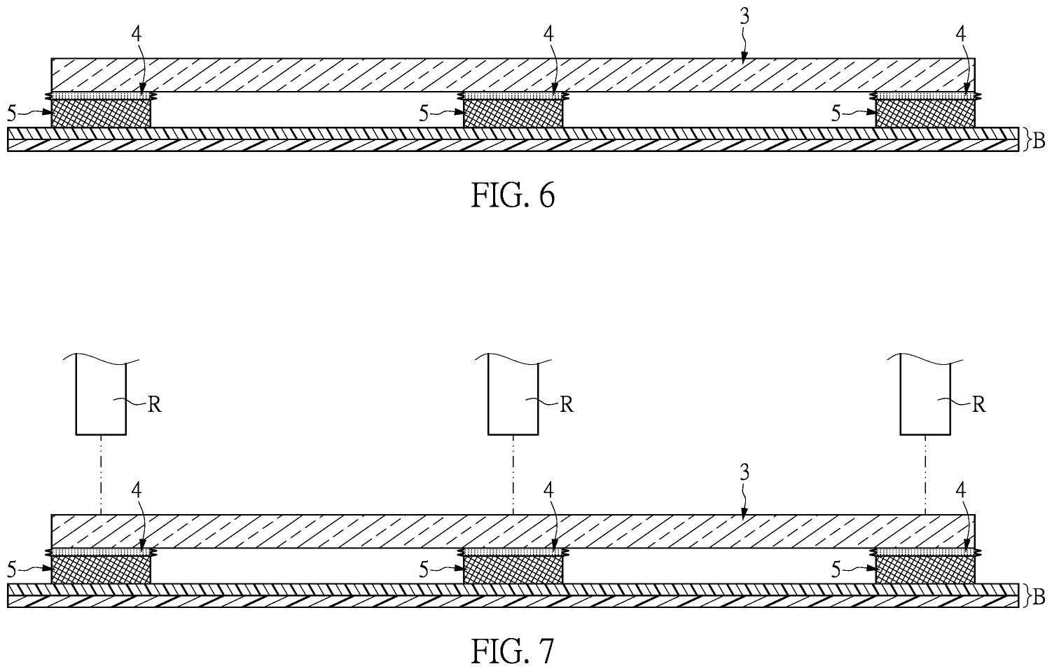

Regarding the steps S302 and S303, as shown in FIGS. 5 and 6, the die-bonding film layer 5 having the plurality of second windows 50 forms on a surface of the base layer B. Then, the light-permeable element 3 is inverted onto the die-bonding film layer 5, and the photoresist layer 4 can be precisely adhered to the die-bonding film layer 5 by way of the plurality of first windows 40 respectively corresponding to the plurality of second windows 50.

Step S304: performing a slicing process to slice the light-permeable element 3, the photoresist layer 4, and the die-bonding film layer 5 to form at least one package cover C.

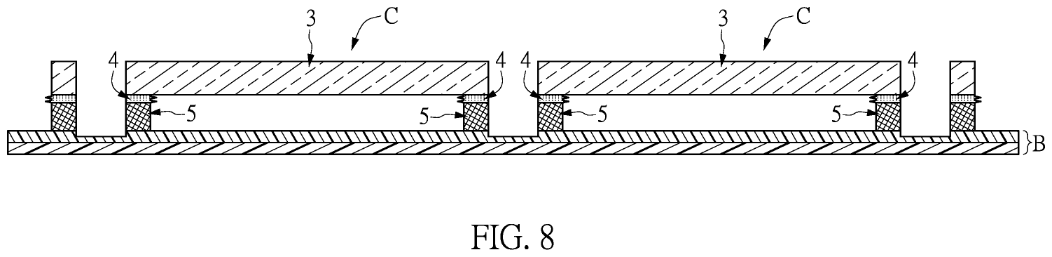

Regarding the step S304, as shown in FIGS. 7 and 8, the structure in which the light-permeable element 3 is inverted onto the die-bonding film layer 5 can be sliced to form the at least one package cover C through a cutting tool

R. The at least one package cover C includes the light-permeable element 3, the photoresist layer 4, and the die-bonding film layer 5. Furthermore, as shown in FIGS. 7 and 8, the cutting tool R has a fixed cutting position and a cutting width, such that a width of the die-bonding film layer 5 of the molded package cover C can be determined by the size of the second windows 50 (as shown in FIG. 5). The size of the second windows 50 can be predetermined according to the size of the sensing chip 2 and the sensing region 21, and the width of the die-bonding layer 5 can be customized according to the size of the second windows 50.

Step S305: providing a substrate 1 and placing the sensing chip 2 onto the substrate 1 to be electrically connected to the substrate 1, wherein the sensing chip 2 has a sensing region 21, and the sensing region 21 is located on the upper surface 20 of the sensing chip 2.

Step S306: placing the at least one package cover C onto the sensing chip 2, wherein the at least one package cover C and the sensing chip 2 jointly form an enclosed space S, and the sensing region 21 is located in the enclosed space S.

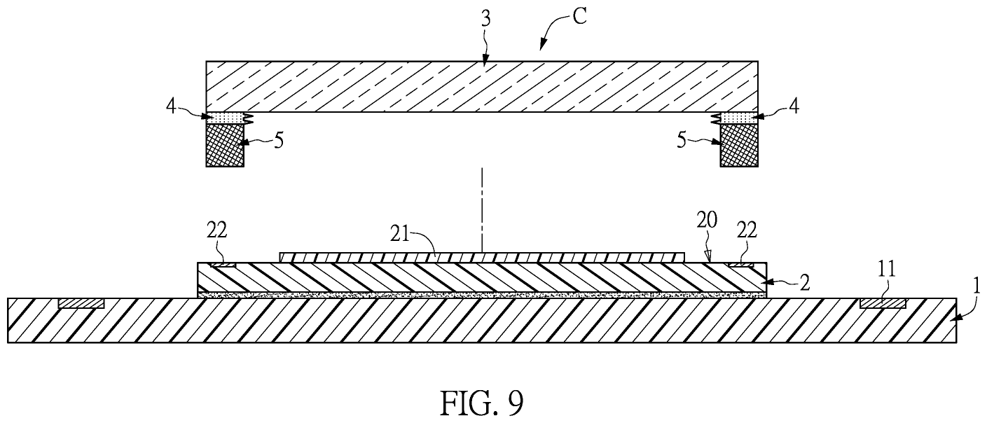

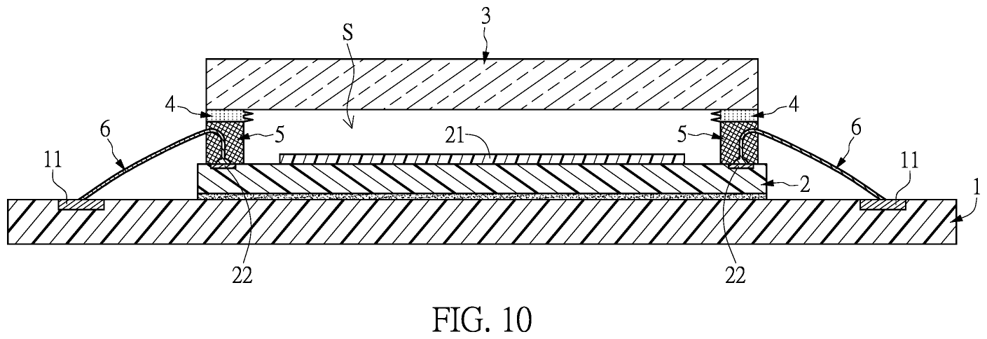

Regarding the steps S305 and S306, as shown in FIGS. 9 and 10, except for the sensing region 21, the remaining area of the upper surface 20 of the sensing wafer 2 forms a carrying region. When the at least one package cover C is disposed on the sensing chip 2, the die-bonding film layer 5 of the at least one package cover C is adhered to the carrying region of the sensing chip 2, such that the sensing chip 2 and the at least one packaging cover C jointly form the enclosed space S. The photoresist layer 4 and the die-bonding film layer 5 jointly surround the sensing region 21, and the sensing region 21 is located in the enclosed space S.

In addition, in the step of electrically connecting the sensing chip 2 to the substrate 1, a plurality of first pads 11 is disposed on the substrate 1, and a plurality of second pads 22 is disposed on the upper surface 20 of the sensing chip 2, The plurality of second pads 22 are located outside the sensing region 21, and the plurality of first pads 11 are respectively connected to the plurality of second pads 22 through a plurality of metal wires 6. When at least one package cover C is disposed on the sensing chip 2, the plurality of second pads 22 are embedded under the die-bonding film layer 5. One end of each of the plurality of metal wires 6 is connected to the plurality of first pads 11, and another end of each of the plurality of metal wires 6 is connected to the plurality of second pads 22 and embedded into the die-bonding film layer 5.

Step S307: placing an encapsulation compound 7 onto the substrate 1, wherein the sensing chip 2, the die-bonding film layer 5, the photoresist layer 4, the plurality of metal wires 6, and a part of the light-permeable element 3 are embedded into the encapsulation compound 7.

Regarding the step S307, as shown in FIG. 1, the encapsulation compound 7 formed as a liquid compound or a molding compound surrounds the at least one package cover C (i.e., the die-bonding film layer 5, the photoresist layer 4 and the light-permeable element 3). The sensing chip 2, the die-bonding film layer 5, the photoresist layer 4, the plurality of metal wires 6, and the part of the light-permeable element 3 are embedded in the encapsulation compound 7, and only a second surface 31B of the light-permeable element 3 is exposed from the encapsulation compound 7.

### Beneficial Effects of the Embodiments

In conclusion, in the sensor package structure and the manufacturing method thereof provided by the present disclosure, by utilizing the die-bonding film layer (i.e., Die Attach Film) instead of the existing adhesive glue as an adhesive material between the light-permeable element and the sensing chip, a width of the adhesive material can be precisely controlled to form a stable colloidal structure on the limited carrying area of the sensing chip and address issues of poor reliability of the existing colloidal structure due to insufficient carrying area of the existing sensing chip and the inclination of the light-permeable element due to the unevenness of the adhesive material.

In the related art, the light-permeable element and the sensing chip adhere to each other through liquid glue. However, the amount of such liquid glues is difficult to control on the surface of the sensing chip because of an insufficient area of the sensing chip. In addition, the cured colloidal structure resulting therefrom is prone to deformation. For example, the middle part of the cured colloidal structure is narrow and the upper and lower parts of the cured colloidal structure are wider, such that a side contour of the cured colloidal structure is arc-shaped. In other words, the structural size of the cured colloidal structure cannot be precisely controlled.

In contrast, the sensor packaging structure M provided by the present disclosure uses the die-bonding film layer 5 as an adhesive material, which can provide good support and is not limited by the carrying area on the surface of the sensing chip. In other words, the die-bonding film layer 5 will not occupy too much of the carrying area on the surface of the sensing chip 2, and the area of the sensing region 21 can be increased as much as possible. Furthermore, an outer edge 21E of the sensing region 21 can extend toward an outer edge 2E of the sensing chip 2 as much as possible. Preferably, a distance D between the outer edge 21E of the sensing region 21 and the outer edge 2E of the sensing chip 2 is less than 400 μm.

Moreover, a height and a width of the die-bonding film layer 5 in the present disclosure can be precisely controlled. Preferably, the width W of the die-bonding film layer 5 is less than 100 μm. The die-bonding film layer 5 can further prevent the light-permeable element 3 from excessively tilting or being broken. Preferably, an inclination of the first surface 31A of the light-permeable element 3 relative to a horizontal plane is less than 10 μm.

In addition, in the method of manufacturing the sensor package structure provided by the present disclosure, the dispensing process in the related art can be omitted, the size of the second windows 50 can be predetermined according to the size of the sensing chip 2 and the sensing region 21, and the width of the die-bonding layer 5 can be customized according to the size of the second windows 50.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate;
a sensing chip disposed on the substrate, wherein an upper surface of the sensing chip has a sensing region;
a light-permeable element disposed above the sensing chip;
a photoresist layer disposed on a first surface of the light-permeable element; and
a die-bonding film layer adhered between the sensing chip and the light-permeable element and surrounding the sensing region.

2. The sensor package structure according to claim 1, further comprising a plurality of metal wires, wherein the substrate includes a plurality of first pads, the sensing chip further includes a plurality of second pads, the plurality of second pads is disposed on the upper surface and embedded under the die-bonding film layer, one end of each of the plurality of metal wires is connected to the plurality of first pads, and another end of each of the plurality of metal wires is connected to the plurality of second pads and embedded into the die-bonding film layer.

3. The sensor package structure according to claim 2, further comprising an encapsulation compound disposed on the substrate, wherein the sensing chip, the die-bonding film layer, the photoresist layer, the plurality of metal wires, and a part of the light-permeable element are embedded in the encapsulation compound.

4. The sensor package structure according to claim 1, wherein one side of the die-bonding film layer facing towards the sensing region has a flat surface, and one side of the photoresist layer facing towards the sensing region has a rough surface.

5. The sensor package structure according to claim 1, wherein a width of the die-bonding film layer and a width of the photoresist layer are smaller than 100 μm.

6. The sensor package structure according to claim 1, wherein a distance between an outer edge of the sensing region and an outer edge of the sensing chip is smaller than 400 μm.

7. The sensor package structure according to claim 1, wherein an inclination of the first surface relative to a horizontal plane is less than 10 μm.

8. A method of manufacturing a sensor package structure, comprising:
providing a light-permeable element and forming a photoresist layer on a first surface of the light-permeable element, wherein a plurality of first windows are formed in the photoresist layer;
forming a die-bonding film layer on a base layer, wherein the die-bonding film layer has a plurality of second windows;
inverting the light-permeable element onto the die-bonding film layer, such that the photoresist layer is adhered to the die-bonding film layer, and the plurality of the first windows respectively correspond to the plurality of the second windows;
performing a slicing process to slice the light-permeable element, the photoresist layer, and the die-bonding film layer to form at least one package cover;
providing a substrate and placing a sensing chip onto the substrate to be electrically connected to the substrate, wherein an upper surface of the sensing chip has a sensing region; and
placing the at least one package cover onto the sensing chip, wherein the at least one package cover and the sensing chip jointly form an enclosed space, and the sensing region is located in the enclosed space.

9. The method according to claim 8, wherein the step of forming the photoresist layer on the first surface of the light-permeable element further includes:
performing a coating process to form a preformed photoresist layer on the first surface of the light-permeable element; and
performing an etching process to form the plurality of first windows on the preformed photoresist layer.

10. The method according to claim 8, wherein the step of forming the photoresist layer on the first surface of the light-permeable element further includes:
performing a screen printing process to directly form the photoresist layer that has the plurality of first windows on the first surface of the light-permeable element.

11. The method according to claim 8, further comprising:
placing a plurality of first pads onto the substrate; and
placing a plurality of second pads onto the upper surface of the sensing chip and at an outer edge of the sensing region; and
electrically connecting the plurality of first pads to the plurality of second pads respectively through a plurality of metal wires.

12. The method according to claim 11, wherein the plurality of second pads are embedded under the die-bonding film layer, one end of each of the plurality of metal wires is connected to the plurality of first pads, and another end of each of the plurality of metal wires is connected to the plurality of second pads and embedded into the die-bonding film layer.

13. The method according to claim 11, further comprising:
placing an encapsulation compound onto the substrate, wherein the sensing chip, the die-bonding film layer, the photoresist layer, the plurality of metal wires, and a part of the light-permeable element are embedded into the encapsulation compound.

14. The method according to claim 8, wherein a distance between an outer edge of the sensing region and an outer edge of the sensing chip is smaller than 400 μm.

15. The method according to claim 8, wherein one side of the die-bonding film layer facing towards the sensing region has a flat surface, and one side of the photoresist layer facing to the sensing region has a rough surface.

16. The method according to claim 8, wherein a width of the die-bonding film layer and a width of the photoresist layer are smaller than 100 μm.

17. The method according to claim 8, wherein an inclination of the first surface relative to a horizontal plane is less than 10 μm.
